(19) United States
(12) Patent Application Publication
(10) Pub. No.: US 2008/0153282 A1
(43) Pub. Date: Jun. 26, 2008

(54) METHOD FOR PREPARING A METAL FEATURE SURFACE

(75) Inventors: Manoj K. Jain, Plano, TX (US); Tae S. Kim, Dallas, TX (US); Stephan Grunow, Wappingers Falls, NY (US)

Correspondence Address: TEXAS INSTRUMENTS INCORPORATED, P O BOX 655474, M/S 3999, DALLAS, TX, 75265, US

(73) Assignee: Texas Instruments, Incorporated, Dallas, TX (US)

(21) Appl. No.: 11/614,185

(22) Filed: Dec. 21, 2006

(51) Int. Cl. H01L 21/02

(52) U.S. Cl. 438/618; 29/592.1

(57) ABSTRACT

Provided is a method for manufacturing an interconnect. The method for manufacturing the interconnect, in one embodiment, includes forming a first metal feature over or within a substrate, the first metal feature having an exposed surface. The method for manufacturing the interconnect may additionally include cleaning the exposed surface using a reactive system with a reducing agent, and subjecting the exposed surface to a plasma etch. The method for manufacturing the interconnect may further include contacting the first metal feature with a second metal feature.

### TECHNICAL FIELD

This disclosure is directed, in general, to a method for preparing a metal feature and, more specifically, to a method for preparing a metal feature surface.

### BACKGROUND

As integrated circuits become denser, the widths of interconnect features that connect transistors and other semiconductor devices of the integrated circuit are reduced. As the widths of interconnect features decrease, their resistance increases. To address this increased resistance, the industry has turned to copper interconnects, as opposed to the traditional aluminum interconnects. Unfortunately, copper is very difficult to etch in most semiconductor process flows.

Because of the difficulty associated with etching copper, damascene processes have been proposed and implemented to form copper interconnects. Damascene methods typically involve forming a trench and/or an opening in a dielectric layer located over a copper-containing structure. Once the trenches or openings are formed, a continuous layer of copper-containing material may be formed over the entire device, and thus contacting the copper-containing structures through the trenches or openings. Thereafter, excess amounts of the copper-containing material may be removed, for example, using chemical-mechanical polishing (CMP).

The copper interconnects, whether formed using the process described above or other processes, experience certain drawbacks. One such drawback is a large amount of electromigration (EM). Another such drawback is increased via stress migration (VSM), and more particularly the inability to reach a VSM saturation point. Other problems also exist.

Accordingly, what is needed in the art is a method for manufacturing an interconnect that does not experience the aforementioned problems of the prior art.

### SUMMARY

To address the above-discussed deficiencies of the prior art, in the embodiment discussed herein, there is provided a method for manufacturing an interconnect. The method for manufacturing the interconnect, in one embodiment, includes forming a first metal feature over or within a substrate, the first metal feature having an exposed surface. The method for manufacturing the interconnect additionally includes cleaning the exposed surface using a reactive system with a reducing agent, and subjecting the exposed surface to a plasma etch. The method for manufacturing the interconnect may further include contacting the first metal feature with a second metal feature.

In an alternative embodiment, a method for manufacturing a semiconductor device is provided. The method for manufacturing the semiconductor device may include forming transistor devices over a substrate, the forming of the transistor devices including forming gate structures over the substrate, and forming source/drain regions in the substrate, the source/drain regions located proximate the gate structures. The method for manufacturing the semiconductor device may further include forming one or more interconnects within dielectric layers located over the one or more transistor devices, as described above.

### BRIEF DESCRIPTION OF THE DRAWINGS

For a more complete understanding of the following discussion, reference is now made to the following descriptions taken in conjunction with the accompanying drawings, in which:

FIGS. 1-6 illustrate views instructing how one might, in one embodiment, manufacture an interconnect structure in accordance with one embodiment; and

FIG. 7 illustrates a view of a semiconductor device incorporating interconnect structures constructed according to another embodiment.

### DETAILED DESCRIPTION

It is presently recognized that neither the cleaning of an exposed surface of a metal feature using a reactive system with a reducing agent (sometimes called in the industry a reactive pre-clean (RPC) step) nor the subjecting of the exposed surface to a plasma etch (sometimes called in the industry a pre-sputter etch (PSE) step), alone, is sufficient to provide a suitably clean surface for the subsequent formation of a material layer thereon. Namely, it has been recognized that the cleaning step, alone, provides insufficient cleanup of residues, oxidized metals, etc. On the other hand, the plasma etch step, alone, provides increased VSM. Accordingly, improved devices may be achieved by using both the cleaning step and plasma etch step.

Based upon these acknowledgements, as well as substantial testing, it has been found that a significant improvement in EM and VSM may be achieved by performing the cleaning step prior to the plasma etch. For example, it has been found that by performing the clean step prior to the plasma etch step, vacancy migration and void density in the underlying metal feature may be reduced. Accordingly, the VSM reliability may be reduced even further.

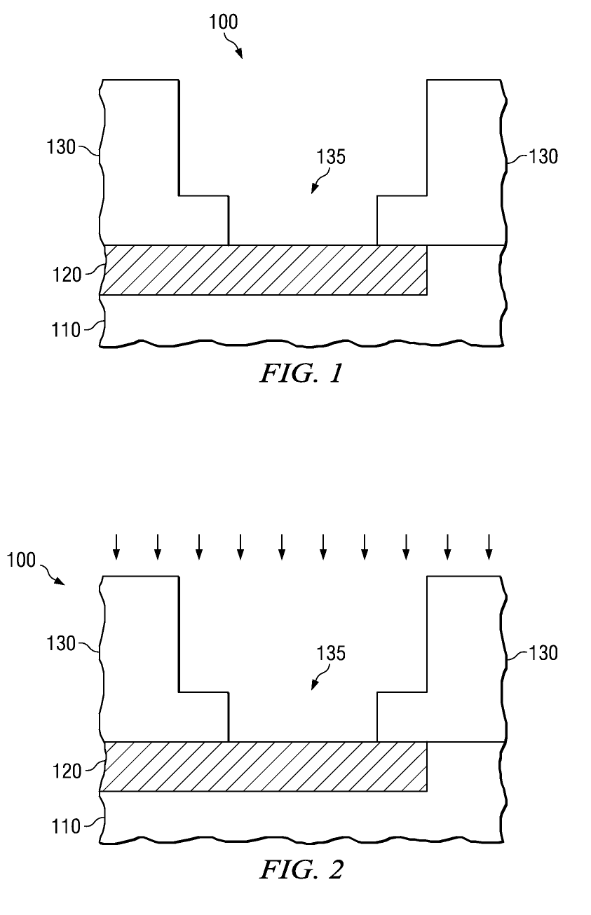

FIGS. 1-6 illustrate how one might, in one embodiment, manufacture an interconnect structure in accordance with one embodiment. FIG. 1 illustrates an interconnect structure 100 at an initial stage of manufacture. The interconnect 100 of FIG. 1 includes a first dielectric layer 110. The layer 110 may be any dielectric layer located within a semiconductor device, such as an interlevel dielectric layer located over one or more transistor devices. Accordingly, the layer 110 may comprise any dielectric material known by those skilled in the art, such as silicon dioxide, a low dielectric constant material, a non-silicon dielectric material, or another material.

Located on, in or over the layer 110 is a first metal feature 120. The feature 120 of FIG. 1 comprises a copper trace in the layer 110. In the illustrated embodiment of FIG. 1, the feature 120 runs into the page. Other embodiments exist, however, wherein the feature 120 comprises a different conductive feature, as well as comprises a different material than copper. For example, it is believed that the feature 120 might comprise a via, or other conductive feature, as well as that the feature 120 might comprise another similar metal, such as a copper alloy, tungsten, tungsten alloy, etc.

Positioned over the layer 110 and the feature 120 is a second dielectric layer 130. The layer 130 may have the same types of properties, comprise the same types of materials, etc., as the layer 110. Located within the layer 130 and exposing the first metal feature 120 is an opening 135. The opening 135 in the layer 130 happens to be a dual damascene opening, however, other embodiments exist wherein the opening 135 is a single damascene or other type of opening. One skilled in the art understands how to form such an opening 135, including possibly performing conventional lithographic and etching techniques on the layer 130. In those embodiments wherein the opening 135 is a dual damascene opening, other layers, such as etch stop layers, may form a portion of the layer 130 to help in the formation of the opening 135.

FIG. 2 illustrates the interconnect 100 of FIG. 1 while an exposed surface of the first metal feature 120 is being cleaned using a reactive system with a reducing agent. The term reactive system, as used throughout this document, is a plasma based clean. The term reducing agent, as used throughout this document, is hydrogen or a combination or hydrogen and one ore more additional elements. The cleaning process, in one embodiment, consists of a reactive hydrogen containing plasma preclean process. For example, the cleaning process might use a mixture of hydrogen gas and helium, with an optional small additional physical etch component (e.g., by using higher RF bias conditions). In one embodiment, the exposed surface of the feature 120 is subjected to the cleaning process for a time period ranging from about 1 seconds to about 60 seconds. In this embodiment, the cleaning process might use a temperature ranging from about −30° C. to about 350° C, an RF power ranging from about 50 Watts to about 500 Watts, a DC bias ranging from about −1000 volts to about 500 volts, and a pressure ranging from about 25 mTorr to about 250 mTorr, in the presence of a flow rate of hydrogen ranging from about 50 sccm to about 150 sccm. While the aforementioned process conditions for the reactive system have been tested, and provide excellent results, other processing conditions, in lieu of or in addition to those mentioned, could also be used.

The cleaning process is configured to treat the exposed surface of the feature 120, for example by reducing the copper oxide there from. The cleaning process is also configured to better lock the copper matrix in place due to the use of the hydrogen (or another similar element) therein, which may lead to an improvement in VSM.

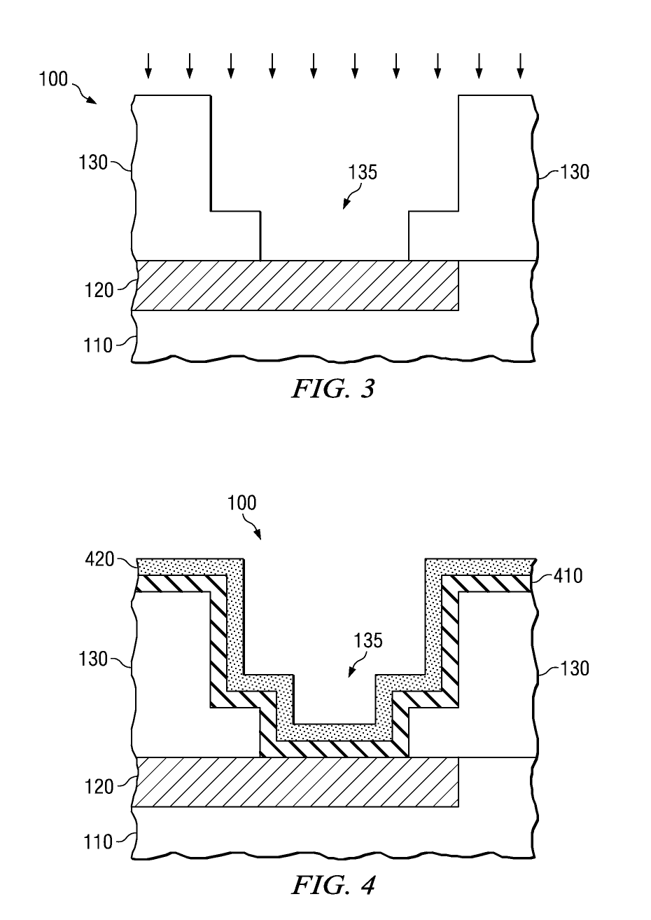

FIG. 3 illustrates the interconnect 100 of FIG. 2 while an exposed surface of the feature 120 is being subjected to a plasma etch. The plasma etch, in this embodiment, consists of an argon based plasma process. Because the plasma etch may be based upon an inert gas, such as argon, it might only contain a physical removal component, and thus no chemical removal component. In one embodiment, the exposed surface of the feature 120 is subjected to the plasma etch for a time period ranging from about 1 seconds to about 60 seconds. In this embodiment, the plasma etch might use a temperature ranging from about −30° C. to about 350° C., a DC bias ranging from about −1000 volts to about 10 volts, a pressure ranging from about 0 mTorr to about 25 mTorr, and an RF power ranging from about 200 Watts to about 350 Watts, in the presence of a flow of argon ranging from about 2 sccm to about 50 sccm. While the aforementioned process conditions for the plasma etch have been tested, and provide excellent results, other processing conditions, in lieu of or in addition to those mentioned, could also be used.

The plasma etch is configured to treat the exposed surface of the first metal feature 120, for example by reducing residues there from. For instance, the plasma etch is particularly adept at removing organic residue, such as hydrocarbons, etc.

The processes of FIGS. 2-3 have been discussed in the context of a cleaning process followed by a plasma etch. As mentioned previously, this order is believed to provide improvement in downstream EM, as well as improvement in VSM. Nevertheless, improvement is achieved over that attainable using conventional processes, just by coupling the cleaning process and plasma etch process into the same process flow. Thus, while the embodiment was originally discussed with the cleaning process first followed by the plasma etch, the opposite order may be used.

FIG. 4 illustrates the interconnect 100 of FIG. 3 after forming a barrier layer 410 and seed layer 420 within the opening 135 in the second dielectric layer 130. In the illustrative embodiment shown, the barrier layer 410 and seed layer 420 are also formed over an upper surface of the layer 130. As those skilled in the art appreciate, the barrier layer 410 is generally configured to substantially reduce, if not prevent, a metal located within the opening 135 in the layer 130 from diffusing into nearby structures, particularly the feature 120. Similarly, as those skilled in the art appreciate, the seed layer 420 is configured to provide a surface upon which a subsequent metal layer can easily be deposited.

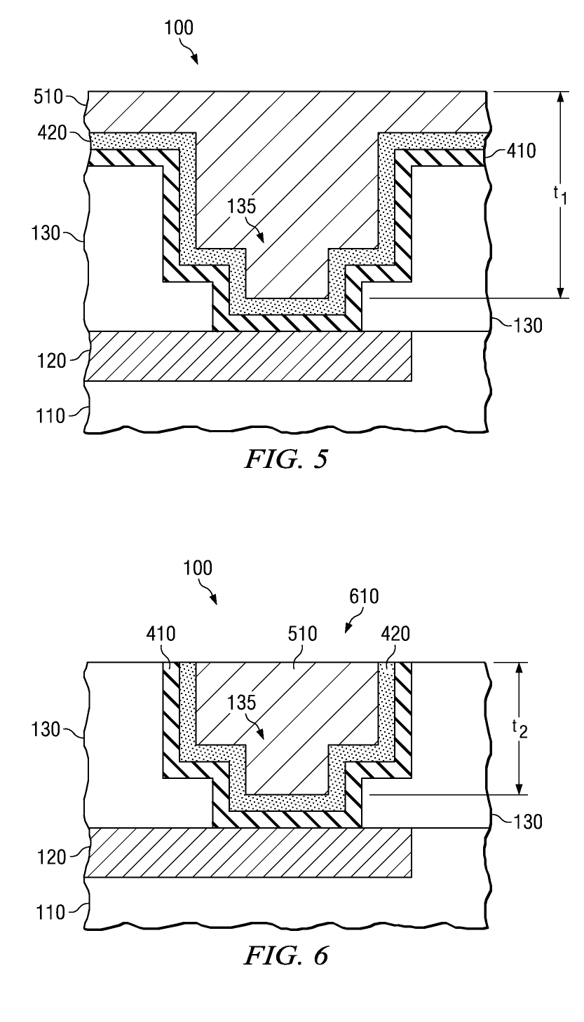

The materials chosen for the barrier layer 410 and seed layer 420 are generally dependent on the particular material being used for the bulk metal layer 510 (FIG. 5). In the given embodiment, however, the bulk metal layer 510 (FIG. 5) comprises copper, and thus the barrier layer 410 might comprise tantalum, tantalum nitride, tungsten alloys, ruthenium or ruthenium alloys, and the seed layer 420 might comprise a copper or copper alloy seed layer. These materials would generally change if the bulk metal layer 510 (FIG. 5) were to comprise a different material, for instance tungsten. Accordingly, the embodiments should not be limited to any specific material.

FIG. 5 illustrates the interconnect structure 100 of FIG. 1 after formation of a bulk metal layer 510 over the barrier layer 410 and seed layer 420, as well as within the opening 135. In the illustrative embodiment of FIG. 5 the layer 510 is formed to an appropriate thickness (t₁) to fill the opening 135. Thus, the layer 510 is also formed over an upper surface of the layer 130 in this embodiment.

In the illustrative embodiment shown in FIG. 5, the layer 510 comprises copper, however, those skilled in the art appreciate that other similar materials, whether currently known or hereafter discovered, may comprise the layer 510. In the particular embodiment where the layer 510 comprises copper, it may be formed using a conventional electroplating process. Were the layer 510 to comprise a different material than copper, an appropriate formation technique could be used to form this different material.

FIG. 6 illustrates the interconnect structure 100 of FIG. 5 after polishing the layer 510, seed layer 420 and barrier layer 410 from the top surface of the second dielectric layer 130. What results is a second metal feature 610 having a lesser thickness (t₂). Those skilled in the art understand the conventional processes that may be used to polish the layer 510, seed layer 420 and barrier layer 410. In the embodiment shown, however, a CMP process was used.

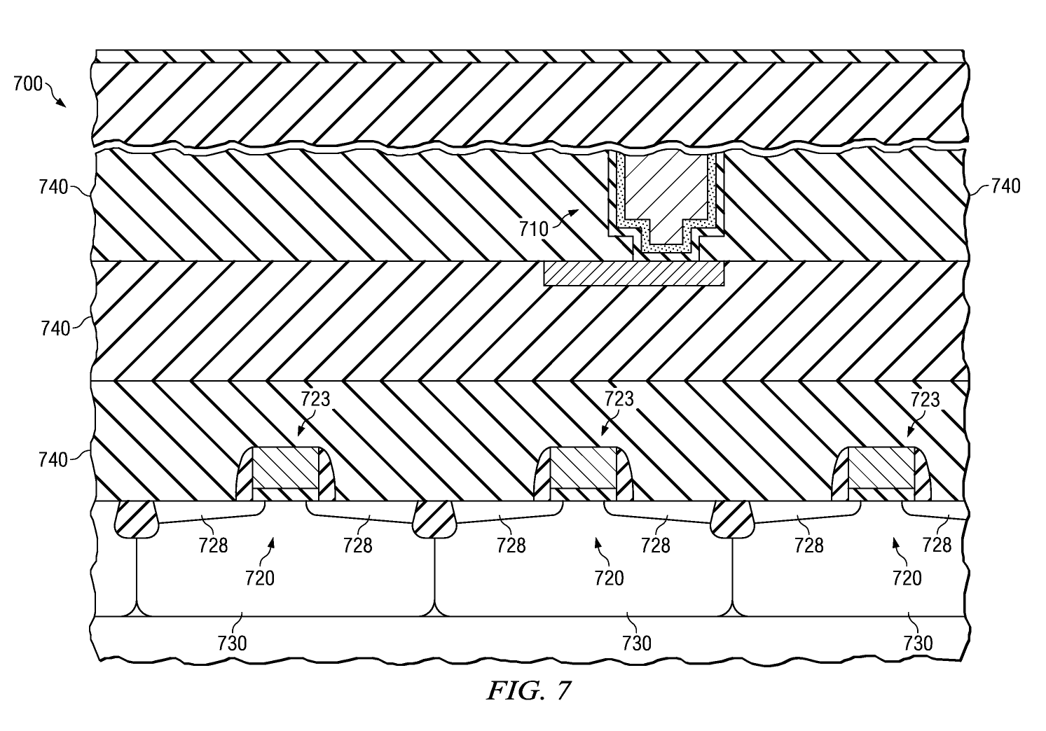

FIG. 7 illustrates a semiconductor device 700 incorporating interconnect structures 710 constructed according to one or more embodiments discussed herein. The semiconductor device 700 may include devices, such as transistors used to form CMOS devices, BiCMOS devices, Bipolar devices, as well as capacitors or other types of devices. The semiconductor device 700 may further include passive devices, such as inductors or resistors, or it may also include optical devices or optoelectronic devices. Those skilled in the art are familiar with these various types of devices and their manufacture. In the particular embodiment illustrated in FIG. 7, the semiconductor device 700 includes transistor devices 720 located over a semiconductor substrate 730. Further located over the transistor devices 720 are dielectric layers 740, the transistor devices including gate structures 723 and source/drain regions 728. As is further illustrated, the interconnect structures 710 may be located within the dielectric layers 740 to interconnect various devices, thus, forming the operational semiconductor device 700.

Those skilled in the art to which the above discussion relates will appreciate that other and further additions, deletions, substitutions and modifications may be made to the described embodiments without departing from the scope herein.

What is claimed is:

1. A method for manufacturing an interconnect, comprising:
forming a first metal feature over or within a substrate, the first metal feature having an exposed surface;
cleaning the exposed surface using a reactive system with a reducing agent;
subjecting the exposed surface to a plasma etch; and
contacting the first metal feature with a second metal feature.

2. The method as recited in claim 1 wherein the cleaning occurs before the subjecting.

3. The method as recited in claim 1 wherein the cleaning has a chemical removal component and the subjecting has no chemical removal component.

4. The method as recited in claim 1 wherein cleaning includes cleaning for a time period ranging from about 1 seconds to about 60 seconds.

5. The method as recited in claim 1 wherein cleaning includes using a temperature ranging from about −30° C. to about 350° C., a DC bias ranging from about −1000 volts to about 500 volts, a pressure ranging from about 25 mTorr to about 250 mTorr, and an RF power ranging from about 50 Watts to about 500 Watts.

6. The method as recited in claim 1 wherein cleaning includes cleaning the exposed surface using a flow rate of hydrogen ranging from about 50 sccm to about 150 sccm.

7. The method as recited in claim 1 wherein subjecting includes subjecting for a time period ranging from about 1 seconds to about 60 seconds.

8. The method as recited in claim 1 wherein subjecting includes using a temperature ranging from about −30° C. to about 350° C., a DC bias ranging from about −1000 volts to about 10 volts, a pressure ranging from about 0 mTorr to about 25 mTorr, and an RF power ranging from about 200 Watts to about 350 Watts.

9. The method as recited in claim 1 wherein subjecting includes subjecting the exposed surface using a flow rate of argon ranging from about 2 sccm to about 50 sccm.

10. The method as recited in claim 1 wherein contacting includes contacting the first metal feature with a barrier layer, a seed layer and a bulk metal layer.

11. The method as recited in claim 10 wherein the barrier layer, seed layer and bulk metal layer form at least a portion of a copper damascene metal feature.

12. The method as recited in claim 1 wherein the cleaning and the subjecting occur through an opening in a dielectric layer located over the first metal feature.

13. An interconnect manufactured using the method described in claim 1.

14. A method for manufacturing a semiconductor device, comprising:
forming transistor devices over a substrate, including
forming gate structures over the substrate; and
forming source/drain regions in the substrate, the source/drain regions located proximate the gate structures; and
forming one or more interconnects within dielectric layers located over the transistor devices, including;
forming a first metal feature over or within at least one of the dielectric layers, the first metal feature having an exposed surface;
cleaning the exposed surface using a reactive system with a reducing agent;
subjecting the exposed surface to a plasma etch; and
contacting the first metal feature with a second metal feature.

15. The method as recited in claim 14 wherein the cleaning occurs before the subjecting.

16. The method as recited in claim 14 wherein cleaning includes cleaning for a time period ranging from about 1 seconds to about 60 seconds using a DC bias ranging from about −1000 volts to about 500 volts, a pressure ranging from about 25 mTorr to about 250 mTorr, and an RF power ranging from about 50 Watts to about 500 Watts.

17. The method as recited in claim 14 wherein subjecting includes subjecting for a time period ranging from about 1 seconds to about 60 seconds using a DC bias ranging from about −1000 volts to about 10 volts, a pressure ranging from about 0 mTorr to about 25 mTorr, and an RF power ranging from about 200 Watts to about 350 Watts.

18. The method as recited in claim 14 wherein contacting includes contacting the first metal feature with a copper damascene metal feature comprising a barrier layer, a seed layer and a bulk metal layer.

19. The method as recited in claim 14 wherein the cleaning and the subjecting occur through an opening in at least one of the dielectric layers.

20. A semiconductor device manufactured using the method described in claim 14.
